(19) United States
(12) Patent Application Publication
(10) Pub. No.: US 2012/0270384 A1
(43) Pub. Date: Oct. 25, 2012

(54) APPARATUS FOR DEPOSITION OF MATERIALS ON A SUBSTRATE

(75) Inventors: ERROL ANTONIO C. SANCHEZ, Tracy, CA (US); RICHARD O. COLLINS, Santa Clara, CA (US); DAVID K. CARLSON, San Jose, CA (US); KEVIN BAUTISTA, San Jose, CA (US); HERMAN P. DINIZ, Fremont, CA (US); KAILASH PATALAY, San Jose, CA (US); NYI O. MYO, San Jose, CA (US); DENNIS L. DEMARS, Santa Clara, CA (US); CHRISTOPHE MARCADAL, Santa Clara, CA (US); STEVE JUMPER, Dublin, CA (US); SATHEESH KUPPURAO, San Jose, CA (US)

(73) Assignee: APPLIED MATERIALS, INC., Santa Clara, CA (US)

(21) Appl. No.: 13/192,101

(22) Filed: Jul. 27, 2011

Related U.S. Application Data
(60) Provisional application No. 61/478,462, filed on Apr. 22, 2011.

(51) Int. Cl. H01L 21/20; C23C 16/455; C23C 16/46

(52) U.S. Cl. 438/503; 118/725; 118/719; 257/E21.09

(57) ABSTRACT

Methods and apparatus for deposition of materials on a substrate are provided herein. In some embodiments, an apparatus for processing a substrate may include a process chamber having a substrate support disposed therein to support a processing surface of a substrate, an injector disposed to a first side of the substrate support and having a first flow path to provide a first process gas and a second flow path to provide a second process gas independent of the first process gas, wherein the injector is positioned to provide the first and second process gases across the processing surface of the substrate, a showerhead disposed above the substrate support to provide the first process gas to the processing surface of the substrate, and an exhaust port disposed to a second side of the substrate support, opposite the injector, to exhaust the first and second process gases from the process chamber.

### CROSS-REFERENCE TO RELATED APPLICATIONS

This application claims benefit of U.S. provisional patent application Ser. No. 61/478,462, filed Apr. 22, 2011, which is herein incorporated by reference.

### FIELD

Embodiments of the present invention generally relate to methods and apparatus for the deposition of materials on a substrate.

### BACKGROUND

As the critical dimensions of complementary metal oxide semiconductor (CMOS) devices continue to shrink, novel materials need to be incorporated into CMOS architecture, for example, to improve energy efficiency and/or speed. One such group of materials is III-V materials, which may be utilized, for example, in the channel of a transistor device. Unfortunately, current processing apparatus and methods fail to yield III-V films having suitable material quality, such as low defect density, composition control, high purity, morphology, in-wafer uniformity, and run to run reproducibility.

Accordingly, the inventors have provided improved methods and apparatus for the deposition of materials on a substrate, such as for example, III-V materials.

### SUMMARY

Methods and apparatus for deposition of materials on a substrate are provided herein. In some embodiments, the inventive methods and apparatus may advantageously be used for the deposition of III-V materials on a substrate. In some embodiments, an apparatus for processing a substrate may include a process chamber having a temperature-controlled reaction volume including interior surfaces comprising quartz and having a substrate support disposed within the temperature-controlled reaction volume to support a processing surface of a substrate, a heating system disposed below the substrate support to provide heat energy to the substrate support, an injector disposed to a first side of the substrate support and having a first flow path to provide a first process gas and a second flow path to provide a second process gas independent of the first process gas, wherein the injector is positioned to provide the first and second process gases across the processing surface of the substrate, a showerhead disposed above the substrate support to provide the first process gas to the processing surface of the substrate, and a heated exhaust manifold disposed to a second side of the substrate support, opposite the injector, to exhaust the first and second process gases from the process chamber.

In some embodiments, a method for depositing a layer on a substrate may include cleaning surfaces in the processing volume, establishing a temperature within the processing volume prior to introducing a substrate into the processing volume, flowing a first process gas into the processing volume and across a processing surface of the substrate, separately flowing the first process gas into the processing volume and towards the processing surface from above the processing surface, flowing a second process gas into the processing volume and across the processing surface, and modulating the temperature of the processing surface of the substrate during formation of one or more layers on the processing surface from the first and second process gases.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1A depicts a schematic side view of a process chamber in accordance with some embodiments of the present invention.

FIG. 1B depicts a schematic top view of a process chamber and service enclosure in accordance with some embodiments of the present invention.

FIG. 2 depicts a partial schematic top view of a process chamber showing the configuration of an injector and an exhaust port of the process chamber in accordance with some embodiments of the present invention.

FIGS. 3A-C respectively depict schematic front and side views of injectors in accordance with some embodiments of the present invention.

FIGS. 4A-B respectively depict schematic front views of injectors in accordance with some embodiments of the present invention.

FIG. 5 depicts a schematic side view of a showerhead in accordance with some embodiments of the present invention.

FIG. 6 depicts a flow chart of method for depositing a layer on a substrate in accordance with some embodiments of the present invention.

FIG. 7 depicts a layer deposited on a substrate in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Methods and apparatus for deposition of materials on a substrate are provided herein. In some embodiments, the inventive methods and apparatus may advantageously be used for the deposition of III-V materials on a substrate. Embodiments of the inventive methods and apparatus may advantageously provide for the deposition of improved III-V films suitable, for example, for CMOS applications. In at least some embodiments, the improved apparatus may meet some or all of the expectations placed by the mainstream semiconductor industry on current epitaxial silicon and silicon-germanium reactors. For example, in some embodiments, the improved apparatus may facilitate epitaxial film growth on, for example, a 300 mm silicon wafer, with better material quality (e.g., one or more of lower defect density, good composition control, higher purity, good morphology, and higher uniformity) within a particular substrate and from run to run, as compared to conventional commercial reactors. In at least some embodiments, the improved apparatus may provide reliable operation and extended reactor (and process) stability, with much less residue accumulation for less frequent maintenance cycles and intervention. In at least some embodiments, the improved apparatus may provide for safe and efficient servicing of the apparatus, thereby leading to reduced downtime and high overall availability of the apparatus. Thus, the improved apparatus and methods of use described herein may advantageously provide for improved deposition of III-V materials in CMOS device production as compared to conventional commercial reactors.

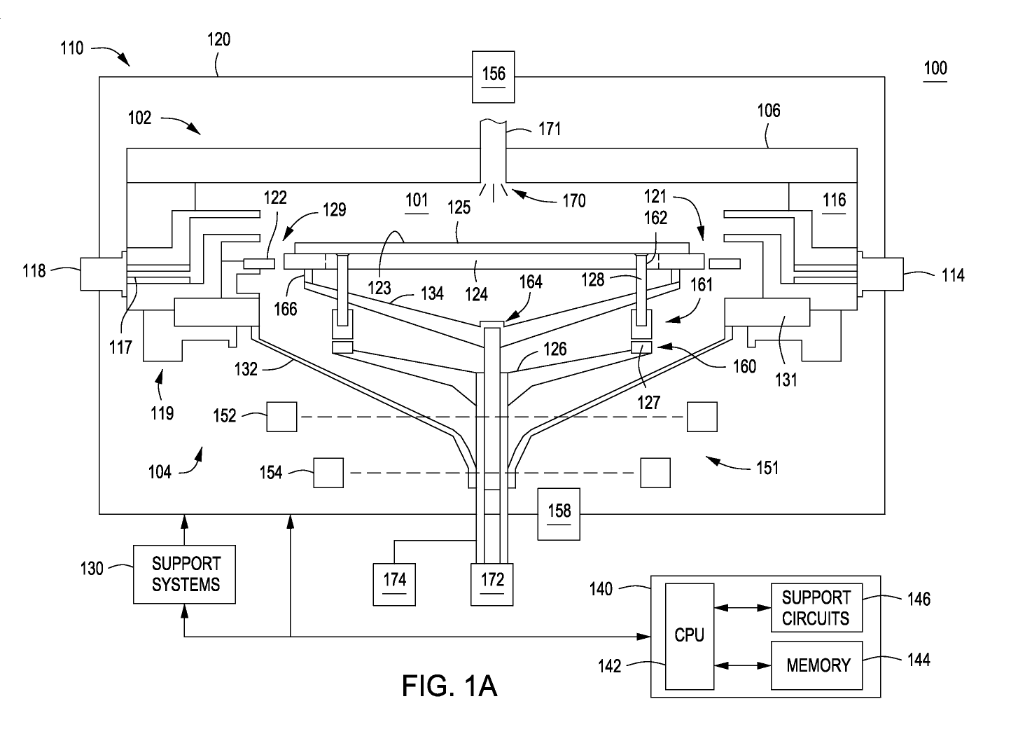

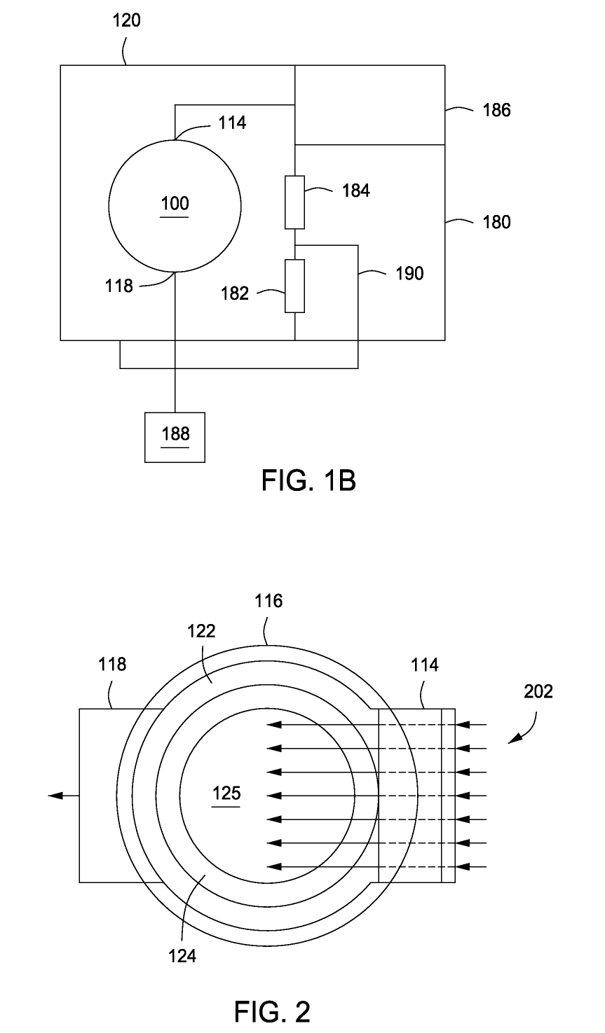

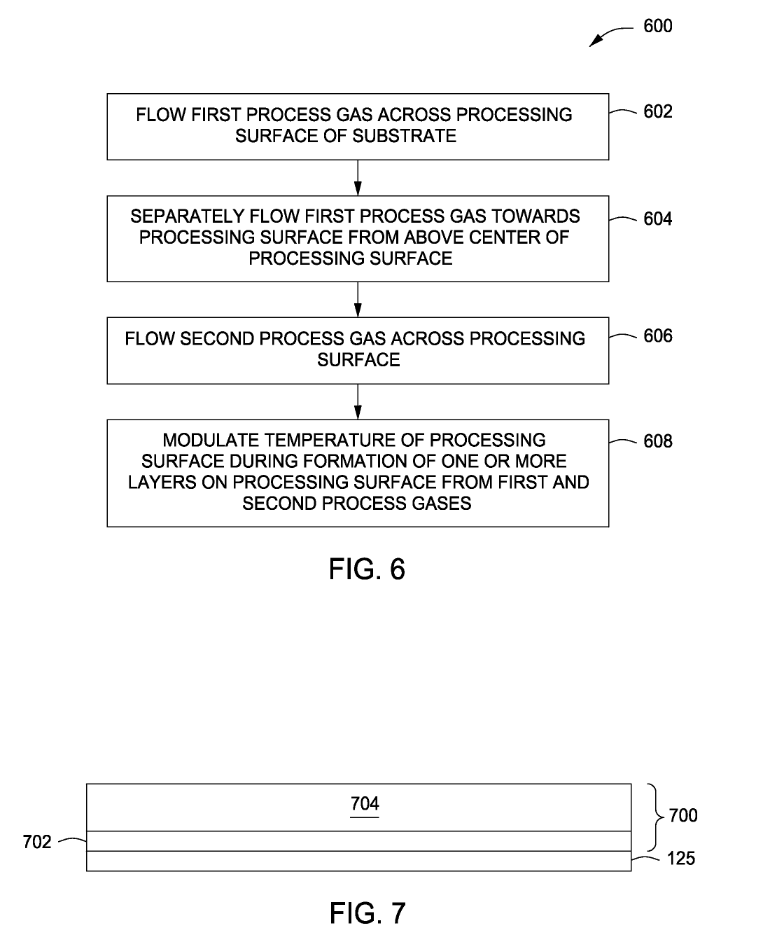

FIG. 1A depicts a schematic side view of a process chamber 100 in accordance with some embodiments of the present invention. In some embodiments, the process chamber 100 may be modified from a commercially available process chamber, such as the RP EPI® reactor, available from Applied Materials, Inc. of Santa Clara, Calif., or any suitable semiconductor process chamber adapted for performing epitaxial silicon deposition processes. The process chamber 100 may be adapted for performing epitaxial deposition processes, for example as discussed below with respect to the method of FIG. 6, and illustratively comprises a chamber body 110, a temperature-controlled reaction volume 101, an injector 114, an optional showerhead 170, and a heated exhaust manifold 118. The process chamber 100 may further include support systems 130, and a controller 140, as discussed in more detail below.

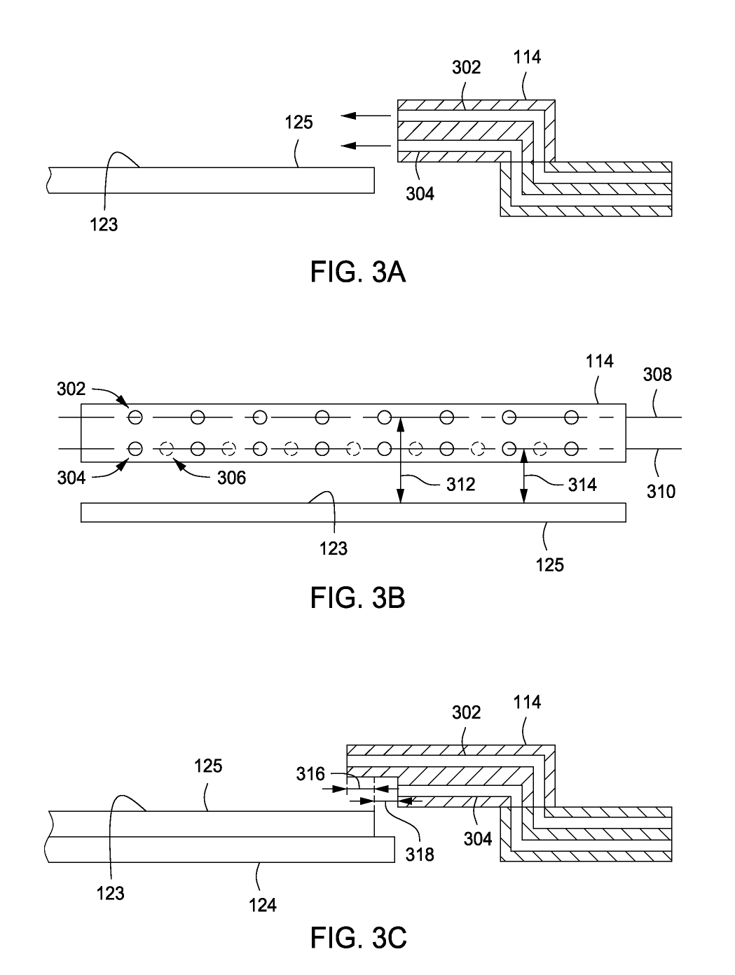

The injector 114 may be disposed on a first side 121 of a substrate support 124 disposed inside the chamber body 110 to provide a plurality of process gases, such as a first process gas and a second process gas across a processing surface 123 of a substrate 125 when the substrate is disposed in the substrate support 124. The plurality of process gases may be provided, for example, from a gas panel 108. The injector 114 may have a first flow path to provide the first process gas and a second flow path to provide the second process gas independent of the first process gas. Embodiments of the first and second flow paths are discussed below with respect to FIGS. 3A-B and 4A-B.

The heated exhaust manifold 118 may be disposed to a second side 129 of the substrate support 124, opposite the injector 114, to exhaust the first and second process gases from the process chamber 100. The heated exhaust manifold 118 may include an opening that is about the same width as the diameter of the substrate 125 or larger. The heated exhaust manifold may include an adhesion reducing liner 117. For example, the adhesion reducing liner 117 may comprise one or more of quartz, nickel impregnated fluoropolymer, or the like.

The chamber body 110 generally includes an upper portion 102, a lower portion 104, and an enclosure 120. The upper portion 102 is disposed on the lower portion 104 and includes a chamber lid 106 and an upper chamber liner 116. In some embodiments, an upper pyrometer 156 may be provided to provide data regarding the temperature of the processing surface of the substrate during processing. Additional elements, such as a clamp ring disposed atop the chamber lid 106 and/or a baseplate on which the upper chamber liner may rest, have been omitted from FIG. 1A, but may optionally be included in the process chamber 100. The chamber lid 106 may have any suitable geometry, such as flat (as illustrated) or having a dome-like shape (not shown), or other shapes, such as reverse curve lids are also contemplated. In some embodiments, the chamber lid 106 may comprise a material, such as quartz or the like. Accordingly, the chamber lid 106 may at least partially reflect energy radiated from the substrate 125 and/or from lamps disposed below the substrate support 124. In embodiments where the showerhead 170 is provided and is a separate component disposed below the lid (not shown), the showerhead 170 may comprise a material such as quartz or the like, for example, to at least partially reflect energy as discussed above. The upper chamber liner 116 may be disposed above the injector 114 and heated exhaust manifold 118 and below the chamber lid 106, as depicted. In some embodiments the upper chamber liner 116 may comprises a material, such as quartz or the like, for example, to at least partially reflect energy as discussed above. In some embodiments, the upper chamber liner 116, the chamber lid 106, and a lower chamber liner 131(discussed below) may be quartz, thereby advantageously providing a quartz envelope surrounding the substrate 125.

The lower portion 104 generally comprises a baseplate assembly 119, a lower chamber liner 131, a lower dome 132, the substrate support 124, a pre-heat ring 122, a substrate lift assembly 160, a substrate support assembly 164, a heating system 151, and a lower pyrometer 158. The heating system 151 may be disposed below the substrate support 124 to provide heat energy to the substrate support 124. The heating system 151 may comprise one or more outer lamps 152 and one or more inner lamps 154. Although the term “ring” is used to describe certain components of the process chamber, such as the pre-heat ring 122, it is contemplated that the shape of these components need not be circular and may include any shape, including but not limited to, rectangles, polygons, ovals, and the like. The lower chamber liner 131 may be disposed below the injector 114 and the heated exhaust manifold 118, for example, and above the baseplate assembly 119. The injector 114 and the heated exhaust manifold 118 are generally disposed between the upper portion 102 and the lower portion 104 and may be coupled to either or both of the upper portion 102 and the lower portion 104.

FIG. 2 depicts a partial schematic top view of the process chamber 100 showing the configuration of the injector 114 and the heated exhaust manifold 118. As illustrated, the injector 114 and the heated exhaust manifold 118 are disposed on opposing sides of the substrate support 124. The injector 114 may include a plurality of injector ports 202 to provide the process gases to the inner volume of process chamber 100. The plurality of injector ports 202 may be disposed periodically along a substrate facing edge of the injector 114 in a pattern suitable to provide a flow of the first and second process gases substantially across the processing surface 123 of the substrate 125. For example, the plurality of injector ports 202 may be disposed periodically along the substrate facing edge of the injector 114 from a first side of the injector 114 proximate a first side of the substrate 125 to an opposing second side of the injector 114 proximate a second side of the substrate 125. The heated exhaust manifold 118 may include an opening that is about the same width as the diameter of the substrate 125 or larger to facilitate removing the excess process gases and any process byproducts from the chamber while maintaining substantially laminar flow conditions.

In some embodiments, the plurality of injector ports 202 may be configured to provide the first and second process gases independently of each other. For example, the first process gas may be provided by a plurality of first injector ports and the second process gas may be provided by a plurality of second injector ports. The size, number, and configuration of the plurality of first injector ports may be controlled to provide a desired flow of the first process gas across the processing surface of the substrate. The size, number, and configuration of the plurality of second injector ports may be independently controlled to provide a desired flow of the second process gas across the processing surface of the substrate. In addition, the relative size, number, and configuration of the plurality of first injector ports as compared to the plurality of second injector ports may be controlled to provide a desired concentration or flow pattern of the first process gas relative to the second process gas across the processing surface of the substrate.

In some embodiments, as illustrated in cross sectional view in FIG. 3A, the injector 114 may include a plurality of first injector ports 302 (e.g., a first flow path) to inject the first process gas and a plurality of second injector ports 304 (e.g., a second flow path) to inject the second process gas. As illustrated in FIG. 3A, the pluralities first and second injector ports 302, 304 may be in a non-planar arrangement with respect to each other. In some embodiments, each of the plurality of first injector ports 302 may be disposed above each of the plurality of second injector ports 304 (or vice-versa). Each of the plurality of first injector ports 302 may be disposed above each of the plurality of second injector ports 304 in any desired arrangement, such as in a parallel planar arrangement, as illustrated in FIG. 3B. For example, a parallel planar arrangement may be where the pluralities of first and second injector ports 302, 304 are disposed in separate planes, wherein each plane is parallel to the processing surface 123 of the substrate 125. For example, as illustrated in FIG. 3B, each of the plurality of first injector ports 302 is disposed along a first plane 308 at a first height 312 above the substrate 125 and each of the plurality of second injector ports 304 is disposed along a second plane 310 at a second height 314 above the substrate 125 that differs from the first height 312. In some embodiments, respective ones of the plurality of first injector ports 302 may be disposed directly above (e.g., in vertical alignment with) corresponding ones of the plurality of second injector ports 304. In some embodiments, one or more individual ports of the first and second injector ports 302, 304 may be in non-vertical alignment, such as illustrated by dashed injector ports 306 (which may be provided in addition to or alternatively to second injector ports 304, as illustrated, and/or in addition to or alternatively to first injector ports 302).

In some embodiments, for example as illustrated in FIG. 3C, the plurality of first injector ports 302 may be disposed at a first distance 316 from an edge of the substrate 125 when positioned on the substrate support 124 and the plurality of second injector ports 304 may be disposed at a second distance 318 from an edge of the substrate 125 when positioned on the substrate support 124. For example, the phrase “when positioned on the substrate support 124” is meant to be understood as the desired position that the substrate 125 is expected to assume for processing in the process chamber 100. For example, the substrate support 124 may include a lip (not shown) or other suitable positioning mechanisms for getting the substrate 125 in the desired processing position. Accordingly, the first and second distances 316, 318 may be measured from the edge of the substrate 125 when the substrate 125 is in the desired processing position. For example, as illustrated in FIG. 3B, the first and second distances 316, 318 may be different. In some embodiments, the plurality of first injector ports 302 may extend beyond (or further beyond) the edge of the substrate 125 than the plurality of second injector ports 304. For example, the plurality of first injector ports 302 may extend further than the plurality of second injector ports 304 to inject the first process gas further into the temperature-controlled reaction volume 101 than the plurality of second injector ports 304 inject the second process gas because the first process gas may more susceptible to decomposition under temperature conditions than the second process gas. For example, to maximize reaction of the first process gas prior to decomposition, the plurality of first injectors may be positioned to inject the first process gas as far into the temperature-controlled reaction volume 101 prior to exposure of the first process gas to the temperature-controlled reaction volume 101.

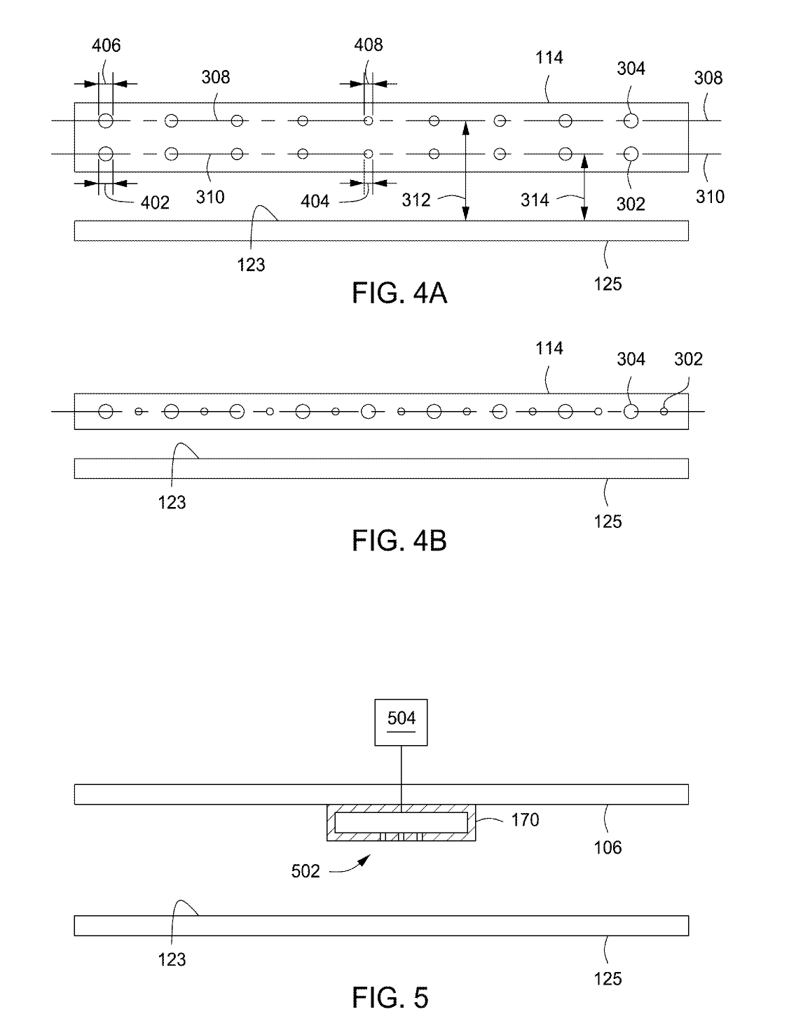

The number, size, and configuration of the first injector ports 302 and the second injector ports 304 may be controlled in numerous combinations to provide various benefits. For example, in some embodiments, some or all of the plurality of first injector ports 302 may have a different diameter than some or all of the plurality of second injector ports 304. Controlling the diameter of the injector ports facilitates control of the velocity of the process gas entering the process chamber via that injection port. A smaller diameter port will provide a process gas at a higher velocity than a larger diameter port at a given upstream pressure. For example, in some embodiments, each of the plurality of second injector ports 304 may have a larger diameter than each of the plurality of first injector ports 302, as shown in FIGS. 4A-4B. For example, each second injector port 302 may have a larger diameter to inject the second process gas at a lower velocity than the first process gas.

Alternatively or in combination, in some embodiments, a first diameter 404 of one of the plurality of first injector ports 302 disposed nearer to a center of the injector may be different than a second diameter 402 of another of the plurality of first injector ports disposed nearer to a edge of the injector 114, as shown in FIG. 4A. Similarly, in some embodiments, a first diameter 408 of one of the plurality of second injector ports 304 disposed nearer to a center of the injector 114 may be different than a second diameter 406 of another of the plurality of second injector ports 304 disposed nearer to a edge of the injector 114. For example, as illustrated in FIG. 4A, the diameters of the first or second injector ports 302, 304 may be gradually reduced from the edge to center of the injector 114, for example, in linearly decreasing reduction scheme or any suitable reduction scheme, non-linear or the like. Alternatively, the diameters of the first or second injector ports 302, 304 may be more coarsely reduced from the edge to the center of the injector 114, for example, such as a stepwise reduction scheme or the like.

Alternatively or in combination, in some embodiments, each of the pluralities of first and second injector ports 302, 304 may be disposed in a co-planar arrangement, as illustrated in FIG. 4B. For example, each of the pluralities of first and second injector ports 302, 304 may be disposed at about the same height above the substrate 125, or in a plane parallel to the processing surface 123 of the substrate 125. In some embodiments, when disposed in a co-planar arrangement, individual ones of the pluralities of first and second injector ports 302, 304 may be alternately disposed, as shown in FIG. 4B. Alternatively, two or more of the first and/or the second injector ports 302, 304 may be grouped together into a subset of first injector ports 302 and/or second injector ports 304 with the subset interposed between adjacent injector ports of the other plurality.

Returning to FIG. 1A, in some embodiments, a showerhead 170 may be disposed above the substrate support 124 (e.g., opposing the substrate support 124) to provide a third process gas to the processing surface 123 of the substrate 125. The third process gas may be the same as the first process gas, the same as the second process gas, or different than the first and second process gases provided by the injector 114. In some embodiments, the third process gas is the same as the first process gas. The third process gas may also be provided, for example, from the gas panel 108.

In some embodiments, for example as illustrated in FIG. 1A, the showerhead 170 may include a single outlet 171 for providing the third process gas to the processing surface 123 of the substrate 125. In some embodiments, as illustrated in FIG. 1A, the single outlet 171 may be disposed in a position that is substantially aligned with a center of the processing surface 123, or with a center of the substrate support 124.

In some embodiments, the showerhead 170 may include a plurality of outlets 502, as illustrated in FIG. 5. In some embodiments, the plurality of outlets 502 may be grouped together (e.g., disposed within a circle having a diameter of no greater than about 4 inches). The plurality of outlets may be disposed in a position that is substantially aligned with a desired area of the processing surface, for example, the center of the processing surface to deliver the first process gas (for example from a gas source 504) to the processing surface 123 of the substrate 125. Although illustrated as having three outlets 502, the showerhead 170 can have any desirable number of outlets suitable for providing the third process gas. In addition, although shown as aligned with the center of the processing surface, the single outlet or the plurality of outlets may be aligned with any desired area of the processing surface to provide the process gases to the desired area of the substrate during processing.

The showerhead 170 may be integral with the chamber lid 106 (as shown in FIG. 1A), or may be a separate component (as shown in FIG. 5). For example, the outlet 171 may be a hole bored into the chamber lid 106 and may optionally include inserts disposed through the hole bored into the chamber lid 106. Alternatively, the showerhead 170 may be a separate component disposed beneath the chamber lid 106. In some embodiments, the showerhead 170 and the chamber lid 106 may both comprise quartz, for example, to limit energy absorption from the lamps 152, 154 or from the substrate 125 by the showerhead 170 or the chamber lid 106.

Embodiments of the injector 114 and, optionally, the showerhead 170 as described above may be utilized to facilitate optimal deposition uniformity and composition control with minimal residue formation. For example, as discussed above, specific reactants, such as the first and second gases, may be directed through independently controllable injector ports of the injector 114 and/or outlets of the showerhead 170. The injection scheme facilitated by the embodiments of the injector 114 and, optionally, the showerhead 170 may allow for matching the flow velocity and/or flow profile of each reactant with its reactivity relative to the other reactants flowing in the process chamber 100. For example, as discussed below the first process gas may be flowed at a higher flow velocity than the second process gas because the first process gas can be more reactive and may dissociate faster than the second process gas. Accordingly, to match the reactivity of the first and second process gases to limit residue formation, optimize uniformity and/or composition, the first process gas may be flowed at a higher velocity than the second process gas. The aforementioned injection scheme is merely exemplary, and other injection schemes are possible.

Returning to FIG. 1A, the substrate support 124 may be any suitable substrate support, such as a plate (illustrated in FIG. 1A) or ring (illustrated by dotted lines in FIG. 1A) to support the substrate 125 thereon. The substrate support assembly 164 generally includes a support bracket 134 having a plurality of support pins 166 coupled to the substrate support 124. The substrate lift assembly 160 comprises a substrate lift shaft 126 and a plurality of lift pin modules 161 selectively resting on respective pads 127 of the substrate lift shaft 126. In one embodiment, a lift pin module 161 comprises an optional upper portion of the lift pin 128 that is movably disposed through a first opening 162 in the substrate support 124. In operation, the substrate lift shaft 126 is moved to engage the lift pins 128. When engaged, the lift pins 128 may raise the substrate 125 above the substrate support 124 or lower the substrate 125 onto the substrate support 124.

The substrate support 124 may further include a lift mechanism 172 and a rotation mechanism 174 coupled to the substrate support assembly 164. The lift mechanism 172 can be utilized to move the substrate support 124 in a direction perpendicular to the processing surface 123 of the substrate 125. For example, the lift mechanism 172 may be used to position the substrate support 124 relative to the showerhead 170 and the injector 114. The rotation mechanism 174 can be utilized for rotating the substrate support 124 about a central axis. In operation, the lift mechanism may facilitate dynamic control of the position of the substrate 125 with respect to the flow field created by the injector 114 and/or the showerhead 170. Dynamic control of the substrate 125 position in combination with continuous rotation of the substrate 125 by the rotation mechanism 174 may be used to optimize exposure of the processing surface 123 of the substrate 125 to the flow field to optimize deposition uniformity and/or composition and minimize residue formation on the processing surface 123.

During processing, the substrate 125 is disposed on the substrate support 124. The lamps 152, and 154 are sources of infrared (IR) radiation (i.e., heat) and, in operation, generate a pre-determined temperature distribution across the substrate 125. The chamber lid 106, the upper chamber liner 116, and the lower dome 132 may be formed from quartz as discussed above; however, other IR-transparent and process compatible materials may also be used to form these components. The lamps 152, 154 may be part of a multi-zone lamp heating apparatus to provide thermal uniformity to the backside of the substrate support 124. For example, the heating system 151 may include a plurality of heating zones, where each heating zone includes a plurality of lamps. For example, the one or more lamps 152 may be a first heating zone and the one or more lamps 154 may be a second heating zone. The lamps 152, 154 may provide a wide thermal range of about 200 to about 900 degrees Celsius. The lamps 152, 154 may provide a fast response control of about 5 to about 20 degrees Celsius per second. For example, the thermal range and fast response control of the lamps 152, 154 may provide deposition uniformity on the substrate 125. Further, the lower dome 132 may be temperature controlled, for example, by active cooling, window design or the like, to further aid control of thermal uniformity on the backside of the substrate support 124, and/or on the processing surface 123 of the substrate 125.

The temperature-controlled reaction volume 101 may be formed by the chamber lid 106 by a plurality of chamber components. For example, such chamber components may include one or more of the chamber lid 106, the upper chamber liner 116, the lower chamber liner 131 and the substrate support 124. The temperature controlled-processing volume 101 may include interior surfaces comprising quartz, such as the surfaces of any one or more of the chamber components that form the temperature-controlled reaction volume 101. The temperature-controlled reaction volume 101 may be about 20 to about 40 liters. The volume 101 may accommodate any suitably sized substrate, for example, such as 200 mm, 300 mm or the like. For example, in some embodiments, if the substrate 125 is about 300 mm, then the interior surfaces, for example of the upper and lower chamber liners 116, 131 may be up to about 50 mm away from the edge of the substrate 125. For example, in some embodiments, the interior surfaces, such as the upper and lower chamber liners 116, 131 may be at a distance of up to about 18% of the diameter of the substrate 125 away from the edge of the substrate 125. For example, in some embodiments, the processing surface 123 of the substrate 125 may be up to about 100 millimeters, or ranging from about 0.8 to about 1 inch from chamber lid 106

The temperature-controlled reaction volume 101 may have a varying volume, for example, the size of the volume 101 may shrink when the lift mechanism 172 raises the substrate support 124 closer to the chamber lid 106 and expand when the lift mechanism 172 lowers the substrate support 124 away from the chamber lid 106. The temperature-controlled reaction volume 101 may be cooled by one or more active or passive cooling components. For example, the volume 101 may be passively cooled by the walls of the process chamber 100, which for example, may be stainless steel or the like. For example, either separately or in combination with passive cooling, the volume 101 may be actively cooled, for example, by flowing a coolant about the chamber 100. For example, the coolant may be a gas.

The support systems 130 include components used to execute and monitor pre-determined processes (e.g., growing epitaxial silicon films) in the process chamber 100. Such components generally include various sub-systems. (e.g., gas panel(s), gas distribution conduits, vacuum and exhaust sub-systems, and the like) and devices (e.g., power supplies, process control instruments, and the like) of the process chamber 100. Exemplary support systems 130 may include the chemical delivery system 186 which is discussed below and illustrated in FIG. 1B.

The controller 140 may be coupled to the process chamber 100 and support systems 130, directly (as shown in FIG. 1A) or, alternatively, via computers (or controllers) associated with the process chamber and/or the support systems. The controller 140 may be one of any form of general-purpose computer processor that can be used in an industrial setting for controlling various chambers and sub-processors. The memory, or computer-readable medium, 144 of the CPU 142 may be one or more of readily available memory such as random access memory (RAM), read only memory (ROM), floppy disk, hard disk, or any other form of digital storage, local or remote. The support circuits 146 are coupled to the CPU 142 for supporting the processor in a conventional manner. These circuits include cache, power supplies, clock circuits, input/output circuitry and subsystems, and the like.

Embodiments of the improved apparatus may provide for safe and efficient servicing of the process chamber 100, thereby leading to reduced downtime and high overall availability of the process chamber 100. For example, as illustrated in FIG. 1B, the enclosure 120 of the process chamber 100 may be accessible by service personnel from a service enclosure 180, which may be disposed adjacent to the enclosure 120. For example, the process chamber 100 may be made accessible to service personnel via a door 182 which may separate the enclosure 120 from the service enclosure 180. Alternatively, or in combination, the process chamber 100 may be made accessible to service personnel in the service enclosure 180 via a glove box 184 disposed between the enclosure 120 and the service enclosure 180. For example, the glove box 184 may allowed controlled access, such as under a controlled atmosphere or the like, to the process chamber 100 and/or components of the process chamber 100 disposed within the enclosure 120. In some embodiments, the service enclosure 180 may further include a chemical delivery system 186, such as a gas cabinet or the like, accessible from and/or disposed within the service enclosure 180. The chemical delivery system 186 may provide the process gases to the process chamber 100 to facilitate desired substrate processing. As shown in FIG. 1B, the enclosure 120 and the service enclosure 180 may be vented, for example separately to a house exhaust system 188. Alternatively, or in combination, the enclosure 120 may be vented to the house exhaust system 188 or to another exhaust system (not shown) via an auxiliary exhaust 190 accessible from the service enclosure 180.

FIG. 6 depicts a flow chart for a method 600 of depositing a layer 700 on the substrate 125. The method 600 is described below in accordance with embodiments of the process chamber 100. However, the method 600 may be used in any suitable process chamber capable of providing the elements of the method 600 and is not limited to the process chamber 100.

The one or more layers 700 is illustrated in FIG. 7 and may be any suitable one or more layers that can be deposited on the substrate 125. For example, the one or more layers 700 may comprises a III-V material. The one or more layers 700 may be an element of a device, for example, such as the channel of a transistor device or the like.

The method 600 may, optionally begin, by cleaning surfaces of, and/or establishing a temperature within, the temperature-controlled reaction volume 101 (e.g., a processing volume) prior to introducing the substrate 125 into the temperature-controlled reaction volume 101. For example, prior to and/or after layer formation on each substrate 125, the chamber 100 may be cleaned in-situ to maintain low particle levels and/or limit residue accumulation on each substrate 125. For example, an in-situ cleaning process may include alternatively flowing the halogen gas and a purge gas through the injector 114 and/or showerhead 170 to purge the chamber of residues or the like. For example, cleaning surfaces of the temperature-controlled reaction volume 101 may include etching the surfaces with a halogen gas and purging the processing volume with an inert gas. For example, the halogen gas may include one or more of chlorine (Cl₂), hydrogen chloride (HCl), nitrogen trifluoride (NF₃), or the like. The halogen gas may be applied to any suitable components of the temperature-controlled reaction volume 101, such as the substrate support 124, the upper and lower chamber liners 116, 131, the chamber lid 106 or the like.

Establishing the temperature within the temperature-controlled reaction volume 101 may include ramping the temperature to any suitable temperature at or near a temperature for performing a process on the processing surface 123 of the substrate 125 and stabilizing the temperature within a desired tolerance level of the desired temperature prior to introducing the substrate 125 into the volume 101.

The method 600 begins at 602 by flowing the first process gas across the processing surface 123 of the substrate 125. The first process gas may be flowed across the processing surface 123 by any of the embodiments discussed above for the plurality of first inlet ports 302 of the injector 114. In some embodiments, the first process gas may dissociate readily and/or may react more quickly than the second process gas. For example, it may be necessary to minimize the residence time of the first process gas in the temperature-controlled reaction volume 101 relative to the second process gas. For example, minimizing the residence time of the first process gas may minimize depletion of the first process gas relative to the second process gas and improve composition and/or thickness uniformity in the one or more layers 700. Accordingly, in some embodiments, a smaller diameter may be provided for the first inlet ports 302 to provide a higher velocity for the first process gas such that the first process gas more rapidly reaches the substrate 125, or the center of the substrate 125, or closer to the center of the substrate 125 prior to dissociating or reacting. As such, the first process gas may be flowed at a higher flow rate than the second process gas. Similarly, in some embodiments, where the diameter of the first inject ports 302 may decrease from the edge to the center of the injector 114 as illustrated in FIG. 3C, the flow rate of the first process gas may be higher across the center of the processing surface than across the edge of the processing surface. In some embodiments, the first process gas may include one or more Group III elements in a first carrier gas. Exemplary first process gases include one or more of trimethylgallium, trimethylindium, or trimethylaluminum. Dopants and hydrogen chloride (HCl) may also be added to the first process gas.

At 604, optionally, the first process gas may be separately flowed towards the processing surface 123 from above the processing surface 123. For example, the first process gas may be flowed from the showerhead 170 using any suitable embodiment of the showerhead 170 as discussed above. The first process gas may be flowed from the showerhead 170 to ensure that an adequate amount of the first process gas reaches the center of the process surface 123 and reacts to form the layer 700, for example, due to the higher reactivity of the first process gas. The first process gas may be flowed from the injector 114 and the showerhead 170 in any suitable scheme, for example, such as simultaneous, alternating, or periodic flow or any suitable flow scheme to provide adequate coverage of the layer 700 over the processing surface 123. Alternatively, an inert gas such as nitrogen (N₂) or hydrogen (H₂) may be flowed towards the processing surface 123 from above the processing surface 123.

At 606, the second process gas may be flowed across the processing surface 123. The second process gas may be flowed across the processing surface 123 by any of the embodiments discussed above for the plurality of second inlet ports 304 of the injector 114. For example, the second process gas may be more slowly dissociated and/or less reactive than the first process gas. Accordingly, the larger diameter for the second inlet ports 304 as discussed above may provide a lower velocity for the second process gas such that the second process enters the process chamber 100 more slowly than the first process gas and can dissociate while moving across a greater portion of the surface of the substrate. As such, the second process gas may be flowed at a lower flow rate than the first process gas. Similarly, because the diameter of the second inject ports 304 may decrease from the edge to the center of the injector 114 as illustrated in FIG. 3C, the flow rate of the second process gas may be higher across the center of the processing surface than across the edge of the processing surface. In some embodiments, the second process gas may include one or more Group V elements in a second carrier gas. Exemplary second process gases include one or more of arsine (AsH₃), phosphine (PH₃), tertiarybutyl arsine, tertiarybutyl phosphine, or the like. Dopants and hydrogen chloride (HCl) may also be added to the second process gas.

The first and second process gases may be flowed from the injector 114 and the showerhead 170 in any suitable scheme, for example, such as simultaneous, alternating, or periodic flow or any suitable flow scheme to provide adequate coverage of the one or more layers 700 over the processing surface 123.

At 608, the temperature of the processing surface 123 of the substrate 125 may be modulated to form one or more layers 700 on the processing surface 123 of the substrate 125 from the first and second process gases. For example, modulating the temperature may include heating and cooling the temperature-controlled processing volume 101, such as heating or cooling any one or more of the components and/or interior surfaces making up the volume 101. For example, heating may include providing energy to a backside surface of the substrate support 124, wherein the substrate rest on the frontside surface of the substrate support 124. Heating may be provided prior and/or during flow of the first and second process gases. Heating may be continuous or discontinuous, and in any desired scheme, such as periodic or the like. Heating may provide any desired temperature profile to the substrate 125 prior to and/or during the flow of the first and second process gases to achieve deposition of the layer 700 on the processing surface 123. Heating may be provided by the lamps 152, 154. The lamps 152, 154 may be capable of increasing the substrate temperature from about 5 degrees Celsius per second to about 20 degrees Celsius per second. The lamps 152, 154 may be capable of providing a temperature to the substrate 125 ranging from about 200 to about 900 degrees Celsius.

The lamps 152, 154 may be utilized in combination with other components, such as the cooling mechanisms and apparatus discussed above to modulate the temperature of the processing surface 123 from about 5 degrees Celsius per second to about 20 degrees Celsius per second. For example, the one or more layers may include a first layer 702 and a second layer 704 deposited atop the first layer 702 as illustrated in FIG. 7. For example, a first layer 702 may be deposited on the processing surface 123 at a first temperature. For example, the first layer 702 may be a nucleation layer or the like. A second layer 704 may be deposited atop the first layer 702 at a second temperature. For example, the second layer 704 may be a bulk layer or the like. In some embodiments, the second temperature may be higher than the first temperature. The deposition of the first and second layers 702, 704 may be repeated, for example, depositing a first layer 702 at a first temperature, depositing the second layer 704 at the second temperature higher than the first temperature, and then depositing an additional first layer 702 atop the second layer 704 at the first temperature, and so on until a desired layer thickness has been achieved.

Additional and/or alternative embodiments of the method 600 are possible. For example, the substrate 125 may be rotated while depositing the one or more layers, such as the first and second layers 702, 704. Separately, or in combination, the position of the process surface 123 may be changed relative to the flow streams of the first and second process gases to adjust composition of the one or more layers. For example, the lift mechanism 174 may be used to raise and/or lower the position of the processing surface 123 relative to the injector 114 and/or showerhead 170 while the first and/or second process gases are flowing to control the composition of the one or more layers.

Thus, improved methods and apparatus for deposition of III-V materials have been provided herein. Embodiments of the inventive methods and apparatus may advantageously provide for the deposition of improved III-V films suitable for CMOS applications as compared to III-V films deposited via conventional deposition apparatus.

While the foregoing is directed to embodiments of the present invention, other and further embodiments of the invention may be devised without departing from the basic scope thereof.

1. An apparatus for processing a substrate, comprising:
a process chamber having a temperature-controlled reaction volume including interior surfaces comprising quartz and having a substrate support disposed within the temperature-controlled reaction volume to support a processing surface of a substrate;
a heating system disposed below the substrate support to provide heat energy to the substrate support;
an injector disposed to a first side of the substrate support and having a first flow path to provide a first process gas and a second flow path to provide a second process gas independent of the first process gas, wherein the injector is positioned to provide the first and second process gases across the processing surface of the substrate;
a showerhead disposed above the substrate support to provide the first process gas to the processing surface of the substrate; and
a heated exhaust manifold disposed to a second side of the substrate support, opposite the injector, to exhaust the first and second process gases from the process chamber.

2. The apparatus of claim 1, wherein the substrate support further comprises:
a rotation mechanism to rotate the substrate support; and
a lift mechanism to position the substrate support relative to the showerhead and the injector.

3. The apparatus of claim 1, wherein the heating system further comprises:
a plurality of heating zones, wherein each one of the plurality of heating zones includes a plurality of lamps.

4. The apparatus of claim 1, wherein the temperature-controlled reaction volume may be at least partially formed by a plurality of chamber components including:
a chamber lid disposed above the substrate support;
an upper chamber liner disposed adjacent to the substrate support and above the injector and the exhaust manifold and below the chamber lid; and
a lower chamber liner disposed adjacent to the substrate support and below the injector and the exhaust manifold

5. The apparatus of claim 4, wherein the showerhead is either disposed in the chamber lid or disposed below the chamber lid.

6. The apparatus of claim 4, wherein the showerhead, the upper chamber liner, the lower chamber liner, the chamber lid, and the injector comprise quartz.

7. The apparatus of claim 1, wherein the injector further comprises:
a plurality of first injector ports to inject the first process gas; and
a plurality of second injector ports to inject the second process gas.

8. The apparatus of claim 7, wherein each of the plurality of second injector ports has a larger diameter than each of the plurality of first injector ports.

9. The apparatus of claim 7, wherein the pluralities of first and second injector ports are disposed in separate planes, wherein each plane is parallel to the processing surface of the substrate.

10. The apparatus of claim 7, wherein the plurality of first injector ports are disposed at a first distance from an edge of a substrate when positioned on the substrate support and the plurality of second injector ports are disposed at a second distance from the edge of the substrate when positioned on the substrate support, where the first distance is different from the second distance.

11. The apparatus of claim 7, wherein one of the plurality of first injector ports has a different diameter than another of the plurality of first injector ports and wherein one of the plurality of second injector ports has a different diameter than another of the plurality of second injector ports.

12. The apparatus of claim 1, wherein the showerhead further comprises:
a single outlet, wherein the single outlet is disposed in a position that is aligned with a center of the processing surface.

13. The apparatus of claim 1, wherein the showerhead further comprises:.
a plurality of outlets, wherein the plurality of outlets are disposed in a position that is aligned with a desired area of the processing surface.

14. The apparatus of claim 1, wherein the heated exhaust manifold further comprises:
an adhesion reducing liner.

15. A method of depositing a layer on a substrate in a processing volume, comprising:
cleaning surfaces in the processing volume;
establishing a temperature within the processing volume prior to introducing a substrate into the processing volume;
flowing a first process gas into the processing volume and across a processing surface of the substrate;
separately flowing the first process gas into the processing volume and towards the processing surface from above the processing surface;
flowing a second process gas into the processing volume and across the processing surface; and
modulating the temperature of the processing surface of the substrate during formation of one or more layers on the processing surface from the first and second process gases.

16. The method of claim 15, wherein the first process gas comprises one or more Group III elements along with dopants and hydrogen chloride (HCl) in a first carrier gas, and wherein the second process gas comprises one or more Group V elements along with dopants and hydrogen chloride (HCl) in a second carrier gas.

17. The method of claim 15, wherein cleaning surfaces in the processing volume further comprises:
etching the surfaces with a halogen gas; and
purging the processing volume with an inert gas.

18. The method of claim 15, wherein the substrate temperature is modulated from about 5 degrees Celsius per second to about 20 degrees Celsius per second while depositing the one or more layers.

19. The method of claim 15, wherein the first process gas is flowed at a different velocity than the second process gas.

20. The method of claim 15, further comprising:
rotating the substrate and varying the position of the processing surface relative to the flow streams while depositing the one or more layers.
